(19) United States
(12) Patent Application Publication
(10) Pub. No.: US 2004/0197712 A1
(43) Pub. Date: Oct. 7, 2004

(54) System for contact printing

(76) Inventors: Joseph M. Jacobson, Newton, MA (US); Eric Jamesson Wilhelm, Somerville, MA (US); Colin A. Bulthaup, Oakland, CA (US); Alexander Henry Slocum, Bow, NH (US); Emily Cathryn Warmann, Cambridge, MA (US)

Correspondence Address: Norma E. Henderson, Esq., Hinckley, Allen & Snyder LLP, 2nd Floor, 43 North Main Street, Concord, NH, 03301-4934, US

(21) Appl. No.: 10/725,686

(22) Filed: Dec. 2, 2003

Related U.S. Application Data
(60) Provisional application No. 60/430,282, filed on Dec. 2, 2002.

(51) Int. Cl. G03F 7/00

(52) U.S. Cl. 430/322; 430/330

(57) ABSTRACT

In a system for contact printing, two surfaces are brought into intimate aligned contact, under controlled pressure, without the entrapment of air. A controlled bow in a stamp pushes air ahead of a moving contact line between the stamp and a substrate. In one embodiment, the bow is created by a difference in pressure between the two sides of a flexible stamp. In an alternate embodiment, a flexible stamp is rolled into contact with the substrate. Alignment of the stamp and any previously patterned features on the substrate is accomplished with an X-Y translation stage or other suitable mechanism. If an optically clear stamp is utilized, features in the stamp and the substrate can be compared simultaneously and the relative position adjusted. In another aspect, a pattern in a thin film of liquid is created by liquid embossing on an offset substrate. The offset substrate is then brought into contact with the final substrate and the high regions of the liquid film are transferred to that substrate. The patterned film may be error-corrected before transfer to the final substrate.

### RELATED APPLICATIONS

This application claims priority to U.S. Provisional Application Ser. No. 60/430,282, filed Dec. 2, 2002.

### FIELD OF THE INVENTION

The present invention relates to printing, microelectronics, to contacting one surface to another surface for printing purposes, and to offset printing and, in particular, to the printing or otherwise all-additive fabrication of electronic circuits, transistors, and micro-electromechanical systems.

### BACKGROUND

Currently, there are increasing demands for non-photolithographic methods of patterning. These needs stem from the high cost, in both time and money, of current photolithography-based fabrication facilities and methods. Photolithographic patterning methods typically must meet a stringent set of requirements, often precluding certain designs and substrates. Issues arising from these requirements may include such things as feature sizes larger than the wavelength of the electromagnetic radiation used to expose and pattern and extremely flat substrates and coatings due to the limited depth of focus of high-resolution photolithographic lenses.

Several existing approaches addressing these issues involve contact between two surfaces. Generally, one surface, known as the stamp, has topographic features that interact with the other surface, known as the substrate. The raised features in the stamp may be inked and then used to transfer material to the substrate, such as in micro-contact printing. The raised features of the stamp may also be used to emboss a film of material on the substrate, creating regions of thick and thin material that can later be used as a resist for etching the underlying substrate, such as in nanoimprint lithography (see, e.g., U.S. Pat. No. 5,772,905). Alternatively, if the stamp has proper optical properties, the raised features can be brought into contact with a film of photoreactive material on the substrate and used to focus energy to expose the material, such as in the process known as step and flash lithography. In another alternative, if the stamp has proper wetting properties, then the raised features can be used to disrupt a thin film of functional liquid material, such as in liquid embossing.

All of these methods share the common theme of bringing the surface of a stamp into intimate contact with the surface of a substrate. Accordingly, all of these techniques suffer from the problems associated with bringing two surfaces into contact, including entrapment of air, total and undeformed contact, lack of repeatability, and control of the pressure between the surfaces. Some of these difficulties are specific to a rigid substrate and rigid stamp, while others are specific to a rigid substrate and flexible stamp.

In accordance with the method described in U.S. Pat. No. 5,947,027, air entrapment may be prevented by reducing the pressure within the stamping chamber. The two rigid surfaces are made parallel before contact by a system of mechanical stops and adjustments, and the pressure during contact is controlled by an air bladder that is pressurized to a known level. This method is complicated, however, and not amenable to rapid changeover of either the stamp or substrate because they are located within a vacuum chamber.

The patterning technique known as liquid embossing (described, for example, in U.S. Pat. No. 6,517,995, and in “All-additive fabrication of inorganic logic elements by liquid embossing,” Bulthaup et al, Applied Physics Letters 79(10):1525-1527, 3 Sep. 2001), has been developed to address some of the limitations inherent in photolithographic patterning. While liquid embossing is fast, all-additive, and can pattern a wide range of liquids on various substrates, there is a maximum line width in liquid embossing that is typically determined by parameters such as the viscosity of the patterned liquid and material often remains in features that are intended to be free of material.

What has been needed, therefore, is an improved liquid embossing technique that avoids the maximum line width and material residue problems. What is further needed is a method or technique for bringing two surfaces into contact for the purpose of patterning that avoids the problems of the current art and is amenable to quick changes of the stamp or the substrate.

### SUMMARY

The present invention is a system for contact printing that overcomes current limitations of photolithographic patterning and liquid embossing. In one aspect, the present invention is a method of, and apparatus for, bringing two surfaces into intimate aligned contact, under controlled pressure, without the entrapment of air, such as for the purpose of contact printing. An embodiment of the present invention utilizes a controlled bow in the stamp to push air ahead of a moving contact line between the stamp and the substrate. In one embodiment, the bow is created by a difference in pressure between the two sides of a flexible stamp. In an alternate embodiment, a flexible stamp is rolled into contact with the substrate. Alignment of the stamp and any previously patterned features on the substrate is accomplished with an X-Y translation stage. If an optically clear stamp is utilized, features in the stamp and the substrate can be compared simultaneously and the relative position adjusted.

In another aspect, the present invention is a method of printing called offset liquid embossing. A pattern in a thin film of liquid is created by liquid embossing on an offset substrate. Liquid embossing creates high and low regions in the liquid film, the low regions resulting from contact with the raised features in the stamp. The offset substrate is then brought into contact with the final substrate and the high regions of the liquid film are transferred to that substrate. Excess material, which is often left in the channels of a liquid embossed device, remains on the offset substrate, leaving only the desired portions of the thin liquid film on the final substrate. This material may then be transferred to yet another final substrate. This second transfer can also act as a cleaning step for the offset substrate. In the preferred embodiment, the contact angle of the liquid embossing stamp is higher than that of the offset substrate and the contact angle of the offset substrate is higher than that of the final substrate, allowing the thin liquid film to be cleanly transferred.

### BRIEF DESCRIPTION OF THE DRAWINGS

The foregoing discussion will be understood more readily from the following detailed description of the invention, when taken in conjunction with the accompanying drawings, in which:

FIG. 1 is a cross-sectional schematic view of an embodiment of a pneumatic stamp according to the present invention;

FIG. 2 is a cross-sectional schematic of the stamp of FIG. 1 coming into contact with a substrate;

FIG. 3 is a cross-sectional schematic of stamp formation according to an example embodiment of the present invention;

FIG. 4 is a model of an example embodiment of a stamp collar according to one aspect of the present invention;

FIG. 5 is a schematic view of a stretched and rolled stamp according to an alternate embodiment of the present invention; and

FIGS. 6a-d present a cross-sectional schematic of an embodiment of the offset liquid embossing process of the present invention, wherein:

FIG. 6a depicts a liquid film being patterned by liquid embossing on an offset substrate;

FIG. 6b depicts the resulting patterned film;

FIG. 6c depicts the final substrate in contact with the pattern on the offset substrate; and

FIG. 6d shows the patterned material transferred to the final substrate.

### DETAILED DESCRIPTION

The present invention is a system for contact printing that overcomes current limitations of photolithographic patterning and liquid embossing. In one aspect, the present invention is a method of bringing two surfaces into intimate aligned contact, under controlled pressure, without the entrapment of air. This method utilizes a controlled bow in the stamp to push air ahead of a moving contact line between the stamp and the substrate. In one embodiment, the bow is created by a difference in pressure between the two sides of a flexible stamp. In a second embodiment, a flexible stamp is rolled into contact with the substrate. Alignment of the stamp and any previously patterned features on the substrate is accomplished by any suitable means known in the art, such as with an X-Y translation stage. If an optically clear stamp is used, features in the stamp and the substrate can be compared simultaneously and the relative position adjusted.

This aspect of the present invention present invention represents an improvement over the prior art for a number of reasons, including that the pressure between the two surfaces can be directly controlled. Changeover from one stamp to another on an X-Y stage can be quickly accomplished by removing and replacing stamps, which can be attached kinematically or otherwise to the stage or other alignment device. The two surfaces need not be parallel for intimate contact and accurate pattern transfer. As air is pushed ahead of the contact line, air entrapment is prevented by the controlled bow of the stamp.

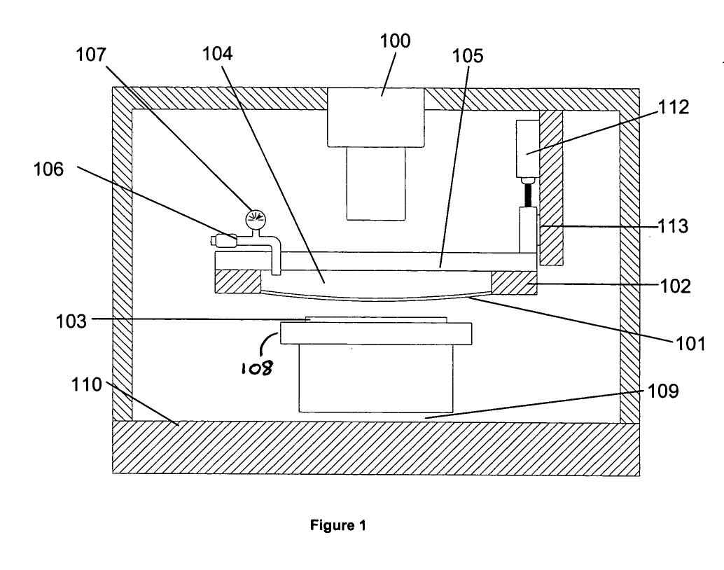

FIG. 1 is a cross-sectional schematic view of an embodiment of a contact printing system in accordance with this aspect of the present invention. In this embodiment, stamp cavity 104 is pressurized with compressed air controlled by valve 106 and measured by gauge 107. This causes stamp 101 to bow outward. A camera or other viewing apparatus 100 allows stamp 101 to be optically aligned with substrate 103 by looking through stamp mounting 105 and stamp 101. Alignment is accomplished by moving an X-Y translation stage, which in the embodiment shown is an air bearing stage having an air gap 109 above a flat smooth surface 110. While a preferred embodiment is depicted, other configurations for positioning stamp 101 with respect to substrate 103 will be readily apparent to those skilled in the art and are within the scope of the present invention. In this embodiment, substrate 103 is held in place by vacuum chuck 108 but any suitable means known in the art may be utilized. In this embodiment, stamp 101 is moved by means of linear bearing 113, controlled by actuator 112. As stamp collar 102 is moved closer to substrate 103, contact is made first as a point and then as a circle of increasing radius that pushes air out from between stamp 101 and substrate 103.

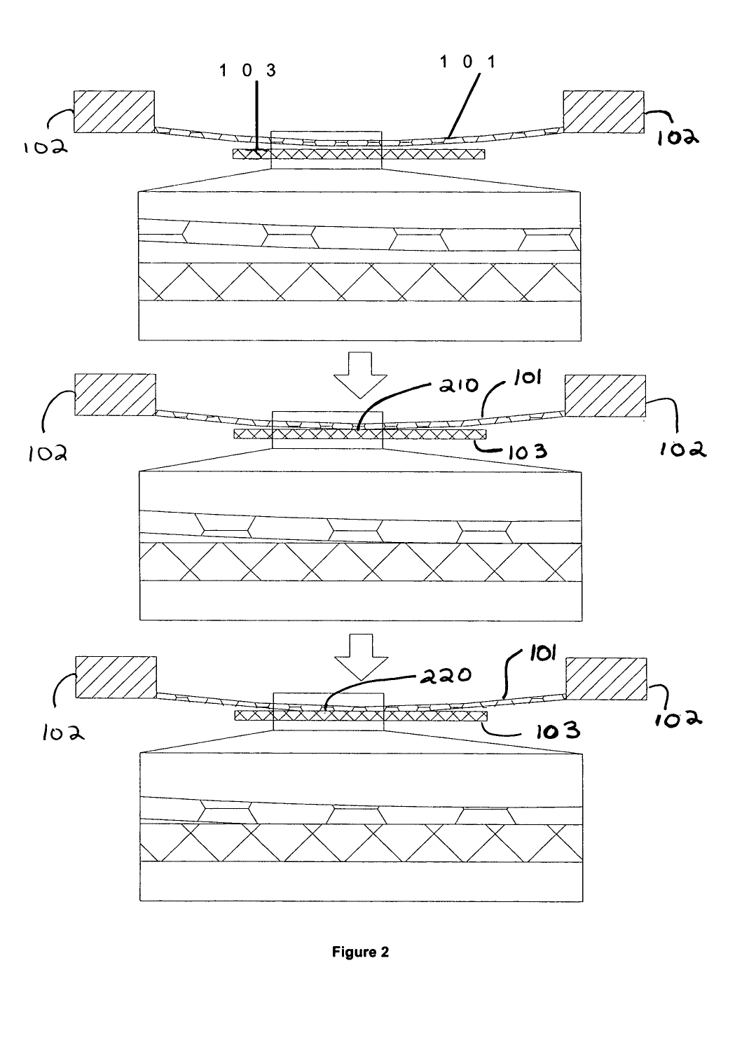

FIG. 2 depicts a cross-sectional view of stamp 101 coming into contact with substrate 103. Inflated stamp 101 is moved toward substrate 103 until it makes contact at a single point 210. The motion of stamp 101 can be controlled so that the stamp/substrate/air interface moves at a predetermined rate. The curvature of stamp 101 ensures that air is forced out before the two surfaces come into full contact 220.

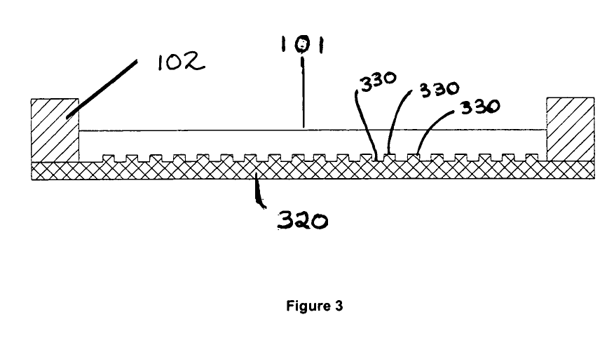

FIG. 3 depicts a cross-sectional view of an example embodiment of stamp formation. Stamp collar 102 is placed on master 320 having surface topography 330. Stamp 101 is made from a flexible material. Preferably, stamp 101 is made from an elastomeric material such as, for example, polydimethylsiloxane (PDMS). In one embodiment, stamp 101 is cast on top of master 320 by pouring PDMS pre-polymer into the cavity formed by stamp collar 102 and master 320, and then curing. Master 320 is then carefully removed, leaving stamp 101 connected to collar 102. While a preferred embodiment of stamp formation is shown, clearly other mechanisms or methods for stamp formation are well known in the art and are also suitable for use in the present invention.

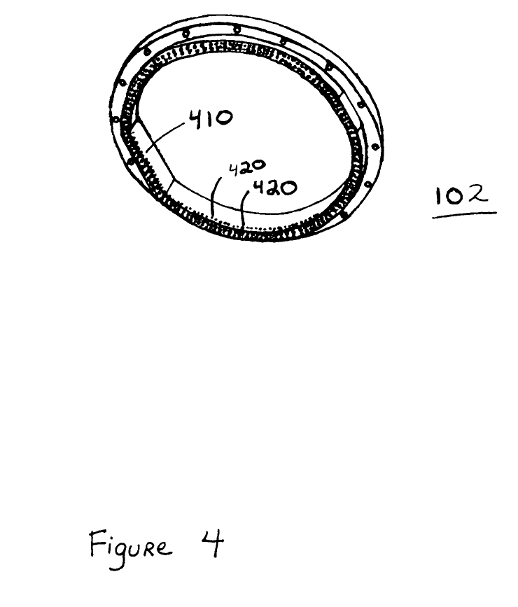

FIG. 4 depicts an example embodiment of stamp collar 102. The surface 410 intended to be in contact with PDMS is desirably porous, so that the pre-polymer flows into the small channels 420 and, once cured, forms a mechanical bond. While a preferred embodiment of stamp collar is shown, many other shapes and constructions of stamp collar are also readily apparent to one of ordinary skill in the art and are suitable for use in the present invention.

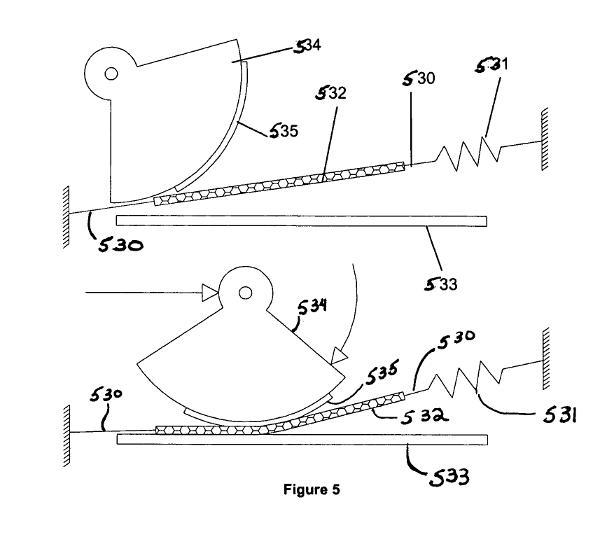

FIG. 5 illustrates another preferred embodiment of a contact printing system according to the present invention. In this embodiment, stamp 532 is formed around support material 530 which is attached to spring 531 that pulls both tight. Substrate 533 is positioned beneath stamp 532 by a translation stage (not shown, but may be similar to FIG. 1 or of any other suitable construction known in the art) and held by a vacuum chuck (not shown, but may be similar to FIG. 1 or of any other suitable construction known in the art). Roller 534 is rolled along stamp 532, bringing stamp 532 into contact with substrate 533. Padding material 535 on roller 534 is used to control the contact pressure. The rolling action of roller 534 pushes air ahead of the contact line. The contact pressure is controlled by the interaction between stamp 532 and substrate 533.

In another aspect, the present invention is a method of printing called offset liquid embossing. A pattern in a thin film of liquid is created by liquid embossing on an offset substrate of controlled surface wettability. Liquid embossing creates high and low regions in the liquid film, the low regions resulting from contact with the raised features in the stamp. The offset substrate is then brought into contact with the final substrate and the high regions of the liquid film are transferred to that substrate. Excess material, which is often left in the channels of a liquid embossed device, remains on the offset substrate, leaving only the desired portions of the thin liquid film on the final substrate. This material may then be transferred to yet another final substrate. This additional transfer can also act as a cleaning step for the offset substrate. In the preferred embodiment, the contact angle of the liquid embossing stamp is higher than that of the offset substrate and the contact angle of the offset substrate is higher than that of the final substrate, allowing the thin liquid film to be cleanly transferred.

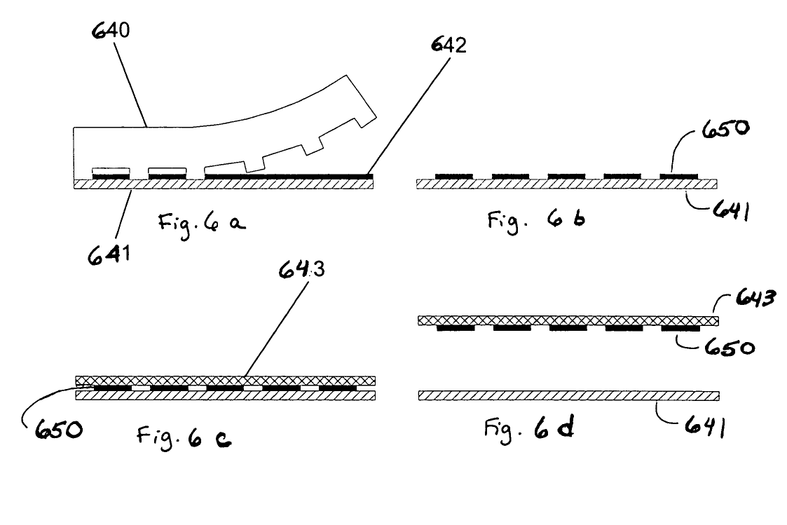

FIGS. 6a-d present a cross-sectional schematic of an embodiment of the contact printing system of the present invention using an offset liquid embossing process. FIG. 6a depicts a film of liquid 642, which is liquid embossed by stamp 640 on offset substrate 641. In the preferred embodiment, the contact angle of offset substrate 641 is lower than that of stamp 640, so that the liquid remains on offset substrate 641 during the liquid embossing process. If stamp 640 is made of PDMS, the offset substrate may be PDMS-treated by oxygen plasma in order to lower its contact angle. FIG. 6b depicts resulting patterned film 650. In FIG. 6c, final substrate 643 is brought into contact with patterned liquid 650. Light pressure is applied to ensure that good contact is made over the entire surface. In the preferred embodiment, the contact angle of final substrate 643 is lower than that of offset substrate 641, so that when final substrate 643 is removed, patterned liquid 650 remains on final substrate 643. In FIG. 6d, patterned material 650 is shown transferred to final substrate 643. After patterned liquid 650 is transferred to final substrate 643, if any material remains on offset substrate 641, it can be transferred onto another final substrate by bringing offset substrate 641 into contact with a second final substrate. This step can be used for patterning or as a cleaning step. Multiple patterns can also be transferred to the same final substrate using this technique.

Preferably, the patterned material is held to the final substrate or previously patterned layers by physical means. However, it can also be held by chemical bonds such as, for example, ionic, hydrogen, or covalent bonds, and may or may not utilize an adhesion layer. The patterned material may also be held to the substrate or previously patterned layers by anodic or thermal compression means or by any other suitable means known in the art.

Multiple offset substrates can also be used. With proper adhesion and surface wetting characteristics, the patterned materials can be transferred from one offset substrate to another before transfer to the final substrate. This procedure can be used, for example, to reverse the patterned material or to control which side of the patterned material contacts the final substrate.

In an example embodiment of the present invention, utilizing offset liquid embossing of a layer of spin-on-glass, an offset substrate is prepared by attaching a thin (approximately 250 μm) sheet of plastic to a glass slide by double-stick tape. PDMS is spin-cast on the surface of the plastic at 1000 RPM for 30 seconds, and cured for at least 2 hours at 60° C. The offset substrate is then plasma treated under 400 mTorr of oxygen at 20 watts of RF power, for 1 minute. Isopropyl alcohol is spin-cast on the surface at 3000 RPM for 20 seconds, followed by spin-casting a 50% (by mass) mixture of 500 FX spin-on-glass (Filmtronics, Butler, Pa.) and alpha-terpineol at 3000 RPM for 20 seconds. The wet film is then patterned by liquid embossing utilizing a pneumatic stamp, such as that shown in FIG. 1. The plastic, with patterned spin-on-glass, is peeled off of the glass slide and placed in contact with a substrate. Light pressure is applied by rubbing the offset substrate and final substrate together, which transfers the patterned spin-on-glass to the final substrate.

In one preferred embodiment, the material being patterned by liquid embossing is heated during the liquid embossing step. In another preferred embodiment, the patterned material is heated during the transfer step. In still another preferred embodiment, the offset substrate is similar to the pneumatic stamp used for liquid embossing in order to allow direct control of the transfer pressure and alignment to previously patterned layers. In yet another preferred embodiment, the liquid embossing stamp and the offset substrate take the form of rolls that roll along a moving sheet of substrate material, in a fashion similar to an offset photolithography press.

In addition, the patterned film may be changed before transfer from the offset substrate to the final substrate. This allows for additions, subtractions, or the correction of errors. In a preferred embodiment, the patterned film on the offset plate is mechanically changed by using a sharp tip to either remove or add material. In another preferred embodiment, material can be added directly, by inkjet or similar type printing, and/or material is removed by addition of a solvent. In yet another preferred embodiment, electromagnetic radiation is used to cure or ablate material from the offset plate. In a preferred embodiment of this, a laser is used to cure the material on the offset plate, thus preventing its transfer to the final substrate.

The present invention, therefore, provides a system for contact printing that allows bringing two surfaces into intimate aligned contact, under controlled pressure, without the entrapment of air. The system of the present invention is amenable to quick changes of the stamp or the substrate. One aspect of the present invention is an improved liquid embossing technique that avoids the maximum line width and material residue problems of the existing techniques. In addition, each of the various embodiments described above may be combined with other described embodiments in order to provide multiple features. Furthermore, while the foregoing describes a number of separate embodiments of the apparatus and method of the present invention, what has been described herein is merely illustrative of the application of the principles of the present invention. Other arrangements, methods, modifications and substitutions by one of ordinary skill in the art are therefore also considered to be within the scope of the present invention, which is not to be limited except by the claims that follow.

What is claimed is:

1. A method for bringing first and second surfaces into contact, comprising the steps of:
bowing the first surface in a controlled manner;
moving the bowed first surface toward the second surface at a predetermined rate until the first surface contacts the second surface at a single point of contact; and
continuing to move the bowed first surface toward the second surface until the single point of contact expands to a circle of desired radius.

2. A method according to claim 1, further comprising the step of aligning the first surface and the second surface before bringing them into contact.

3. A method according to claim 1, wherein the step of bowing is accomplished by pressurization of the first surface.

4. A method according to claim 1, wherein the step of bowing is accomplished by rolling a roller against the first surface.

5. A method for contact printing, comprising the steps of:
applying a thin film of material to an offset substrate;
creating a pattern in the thin film of material by bringing a stamp into contact with the offset substrate; and
transferring the patterned film to a final substrate by bringing the offset substrate into contact with the final substrate.

6. A method according to claim 5 wherein the stamp has a contact angle lower than the contact angle of the offset substrate and the final substrate has a contact angle lower than the contact angle of the offset substrate.

7. A method according to claim 5, further comprising the step of bringing the offset substrate into contact with a second final substrate to transfer any remaining material to the second final substrate.

8. A method according to claim 5, wherein the step of transferring is performed according to the method of claim 1.

9. A method according to claim 5, wherein the step of transferring is performed according to the method of claim 3.

10. A method according to claim 5, wherein the step of transferring is performed according to the method of claim 4.

11. A method according to claim 5, further comprising the step of reversing the patterned film by transferring the patterned film to a second offset substrate before transferring it to the final offset substrate by bringing the offset substrate into contact with the second offset substrate.

12. A method according to claim 5, further comprising the step of heating the material before or while applying it to the offset substrate.

13. A method according to claim 5, further comprising the step of heating the patterned film before or during the step of transferring.

14. A method according to claim 5, further comprising the step of modifying the patterned film before the step of transferring.

15. A method according to claim 14, wherein the step of modifying includes adding material to the patterned film.

16. An apparatus for bringing first and second surfaces into contact, comprising:
means for creating a controlled bow in the first surface; and
means for moving the first surface toward the second surface at a predetermined rate until the desired amount of contact between the first and second surfaces is achieved.

17. An apparatus according to claim 16, further comprising an alignment mechanism to control the relative positions of the first and second substrates.

18. An apparatus according to claim 17, wherein the alignment mechanism includes an optical alignment component.

19. An apparatus according to claim 16, wherein the means for creating a controlled bow is a pressurization mechanism.

20. An apparatus according to claim 16, wherein the means for creating a controlled bow is a roller.

21. An apparatus according to claim 16, wherein the first surface is a stamp made from elastomeric material.

22. An apparatus according to claim 18, wherein the first surface is optically clear.
